(19) United States
(12) Patent Application Publication
(10) Pub. No.: US 2022/0299555 A1
(43) Pub. Date: Sep. 22, 2022

(54) REDUCED IMPEDANCE VARIATION IN A MODULAR 2-TERMINAL TERMINAL CONTACTING ELECTRICAL MEASUREMENT SYSTEM

(71) Applicant: ELECTRO SCIENTIFIC INDUSTRIES, INC., Beaverton, OR (US)

(72) Inventor: Doug GARCIA, Beaverton, OR (US)

(21) Appl. No.: 17/633,828

(22) PCT Filed: Sep. 9, 2020
(86) PCT No.: PCT/US2020/049824

§ 371 Date: Feb. 8, 2022

Related U.S. Application Data
(60) Provisional application No. 62/907,891, filed on Sep. 30, 2019.

(51) Int. Cl. G01R 31/01; H01R 13/24; G01R 1/067

(52) U.S. Cl. CPC G01R 31/016; H01R 13/24; G01R 1/06722

(57) ABSTRACT

An electrical measurement contacting system for use with a component testing system operable to convey devices includes: a first module including a test contact module having a test contact adapted to electrically contact devices conveyed by the component testing system, and a second module including circuitry electrically coupled to the test contact module and operative to perform an electrical measurement on devices conveyed to the test contact. The circuitry is connected, within the second module, to a first conductive path and a second conductive path. The first conductive path and the second conductive path extend into the first module. The first conductive path and the second conductive path are electrically connected to each other and to the test contact module in the first module.

### BACKGROUND

### I. Technical Field

Embodiments of the present invention relate to circuitry and, more particularly, to circuitry for electrical measurement systems.

### II. Description of Related Art

Capacitors, which store electric charge, are one of the basic building blocks of electronic circuits. In its most basic form, a capacitor comprises two conductive surfaces separated from one another by a small distance, wherein a nonconductive dielectric material lies between the conductive surfaces. The capacitance C of such an arrangement is proportional to KA/d, wherein K is the dielectric constant of the dielectric material, A is the area of the opposing conducting surfaces, and d is the distance between the conducting surfaces. A multilayer ceramic capacitor (MLCC) is a type of capacitor made of alternating layers of electrodes and dielectric material (i.e., a ceramic material). MLCCs are commonly used in electronic circuits (e.g., as bypass capacitors, in filters, op-amp circuits, and the like). MLCC manufacturers typically specify their capacitors in terms of parameters such as capacitance (C), dissipation factor (DF), and the like. MLCCs are typically tested to ensure that they fall within acceptable limits before they are sold or used. An MLCC is rejected if it has, for example, an excessively large dissipation factor. To this end, testing systems are employed to perform tests to help measure

Manufacturers typically utilize testing machines to perform industry-standard tests to measure the aforementioned capacitor parameters. In the case of measuring the dissipation factor of an MLCC, it is typically much easier to create a 2-terminal measurement contacting system than it is to create a 4-terminal measurement contacting system. In a 2-terminal measurement contacting system, only two points of electrical contact to an MLCC being tested (also referred to herein as a “device under test” or “DUT”), but circuitry within the measurement contacting system must be able to perform “force” and “sense” functions on a common conductive path for some length/distance. Any variation in electrical resistance along the conductive path will introduce measurement error. Thus a significant variation in electrical resistance can introduce an undesirable amount of measurement error, and so variation in electrical resistance along the conductor should be kept low.

### SUMMARY

An electrical measurement contacting system for use with a component testing system operable to convey devices includes: a first module including a test contact module having a test contact adapted to electrically contact devices conveyed by the component testing system, and a second module including circuitry electrically coupled to the test contact module and operative to perform an electrical measurement on devices conveyed to the test contact. The circuitry is connected, within the second module, to a first conductive path and a second conductive path. The first conductive path and the second conductive path extend into the first module. The first conductive path and the second conductive path are electrically connected to each other and to the test contact module in the first module.

### BRIEF DESCRIPTION OF THE DRAWINGS

FIG. 1 illustrates a perspective view of an electrical measurement contacting system according to an embodiment of the present invention.

FIG. 2 illustrates a perspective view of the electrical measurement contacting system shown in FIG. 1, with the circuit housing and upper module frame for the upper module removed.

FIG. 3 illustrates an enlarged perspective view of the electrical measurement contacting system as shown in FIG. 2. In FIG. 3, the second lower module sub-frame is illustrated as transparent to reveal structures otherwise hidden from view.

FIG. 4 illustrates another enlarged perspective view of the electrical measurement contacting system as shown in FIG. 2.

### DETAILED DESCRIPTION

Example embodiments are described herein with reference to the accompanying drawings. Unless otherwise expressly stated, in the drawings the sizes, positions, etc., of components, features, elements, etc., as well as any distances therebetween, are not necessarily to scale, but are exaggerated for clarity. In the drawings, like numbers refer to like elements throughout. Thus, the same or similar numbers may be described with reference to other drawings even if they are neither mentioned nor described in the corresponding drawing. Also, even elements that are not denoted by reference numbers may be described with reference to other drawings.

The terminology used herein is for the purpose of describing particular example embodiments only and is not intended to be limiting. Unless otherwise defined, all terms (including technical and scientific terms) used herein have the same meaning as commonly understood by one of ordinary skill in the art. As used herein, the singular forms “a,” “an” and “the” are intended to include the plural forms as well, unless the context clearly indicates otherwise. It should be recognized that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Unless otherwise specified, a range of values, when recited, includes both the upper and lower limits of the range, as well as any sub-ranges therebetween. Unless indicated otherwise, terms such as “first,” “second,” etc., are only used to distinguish one element from another. For example, one node could be termed a “first node” and similarly, another node could be termed a “second node”, or vice versa.

Unless indicated otherwise, the term “about,” “thereabout,” etc., means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. Spatially relative terms, such as “below,” “beneath,” “lower,” “above,” and “upper,” and the like, may be used herein for ease of description to describe one element or feature's relationship to another element or feature, as illustrated in the FIGS. It should be recognized that the spatially relative terms are intended to encompass different orientations in addition to the orientation depicted in the FIGS. For example, if an object in the FIGS. is turned over, elements described as “below” or “beneath” other elements or features would then be oriented “above” the other elements or features. Thus, the exemplary term “below” can encompass both an orientation of above and below. An object may be otherwise oriented (e.g., rotated 90 degrees or at other orientations) and the spatially relative descriptors used herein may be interpreted accordingly.

The section headings used herein are for organizational purposes only and, unless explicitly stated otherwise, are not to be construed as limiting the subject matter described. It will be appreciated that many different forms, embodiments and combinations are possible without deviating from the spirit and teachings of this disclosure and so this disclosure should not be construed as limited to the example embodiments set forth herein. Rather, these examples and embodiments are provided so that this disclosure will be thorough and complete, and will convey the scope of the disclosure to those skilled in the art.

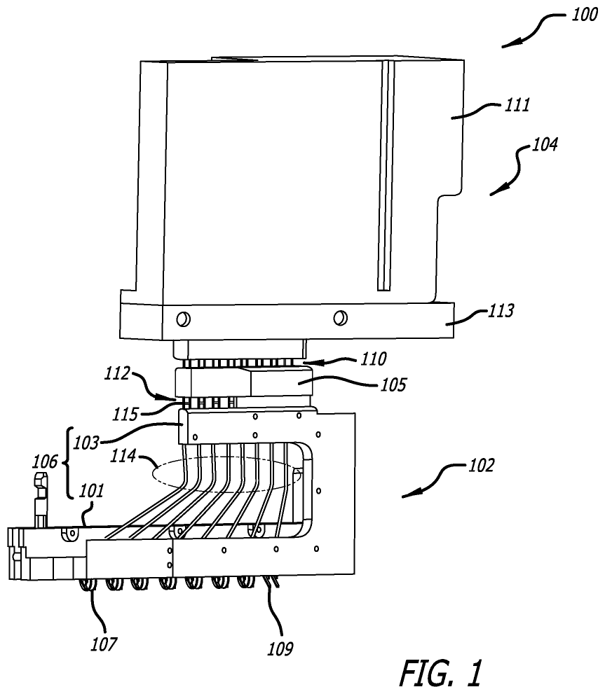

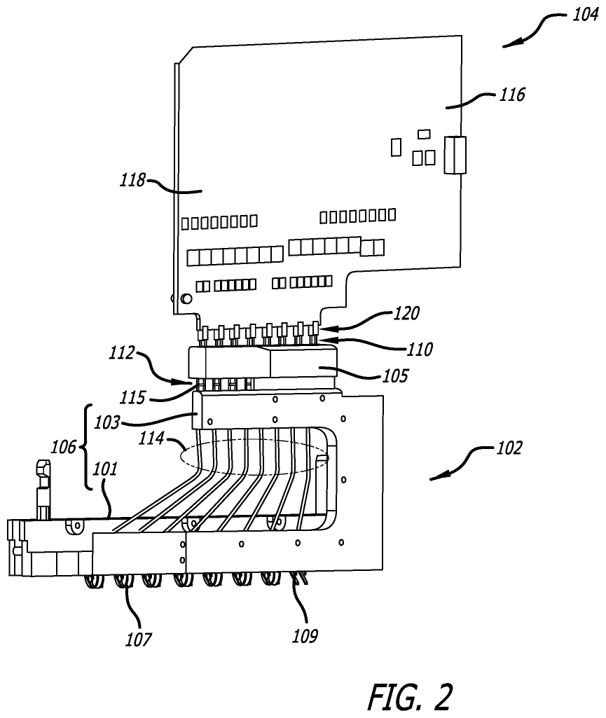

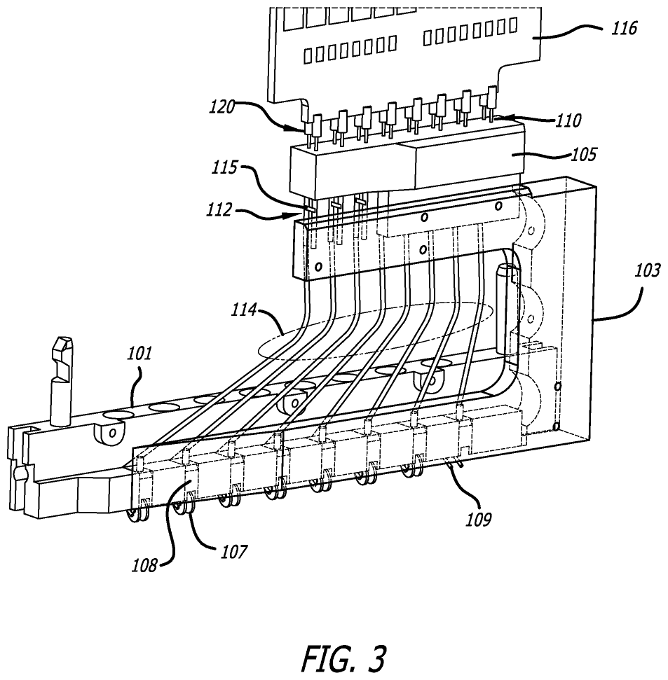

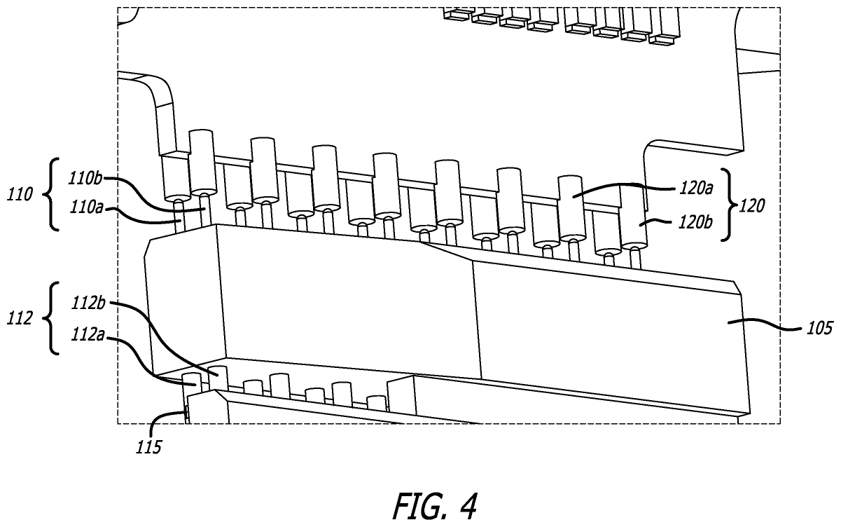

FIG. 1 illustrates a perspective view of an electrical measurement contacting system according to an embodiment of the present invention. FIG. 2 illustrates a perspective view of the electrical measurement contacting system shown in FIG. 1, with the circuit housing and upper module frame for the upper module removed. FIG. 3 illustrates an enlarged perspective view of the electrical measurement contacting system as shown in FIG. 2. In FIG. 3, the second lower module sub-frame is illustrated as transparent to reveal structures otherwise hidden from view. FIG. 4 illustrates another enlarged perspective view of the electrical measurement contacting system as shown in FIG. 2.

Referring to FIG. 1, the electrical measurement contacting system 100 is provided as a 2-terminal electrical measurement contacting system, and includes a lower module 102 and an upper module 104. The electrical measurement contacting system 100 is typically held in place over a movable carrier plate of a component testing system (not shown) designed to convey devices to be tested by the electrical measurement contacting system 100 (e.g., the electrical circuit component handler described in U.S. Pat. No. 5,842,579). As will be described in greater detail below, the lower module 102 contains test contacts which touch a DUT during testing, and the upper module 104 contains circuitry operative to apply a test voltage to the DUT (via the lower module 102) and measure (via the lower module 102) the response of the DUT to the applied voltage. The lower module 102 can include a compliant connector, such as an electrically-conductive contacting pin, which is used to electrically connect circuitry in the upper module 104 to test contacts in the lower module 102, thus forming the aforementioned “conductive path.”

The lower module 102 may be selectively detachable to the component testing system (i.e., relative to the upper module 104) to permit replacement of one lower module 102 (e.g., containing test contacts which have been used in many DUT testing cycles) with another lower module 102 (e.g., containing a fresh set of test contacts). Accordingly, each of the lower module 102 and the upper module 104 can be independently coupled to the component testing system by any suitable means known in the art. The inventor has discovered, however, that the contact resistance of the conductive path at the interface of the compliant connector in the lower module 102 and an electrical conductor in the upper module 104 can vary whenever the lower module 102 (and, thus, the compliant connector therein) is replaced. Variance in the contact resistance can occur even when high quality (i.e., low resistance) compliant connectors are used in the lower modules 102. Constructed as described in greater detail below, the electrical measurement contacting system 100 is adapted to prevent measurement error due to resistance variation within the portion of the circuitry that performs the “high potential” and “high sense” functions on a common conductor.

Referring to FIGS. 1 to 4, the lower module 102 includes a lower module frame 106, a plurality of test contact modules 108 (see FIG. 3), a plurality of pairs of compliant connectors 110 (as best shown in FIGS. 2 to 4 and, for example, each pair consisting of a first compliant connector 110a and a second compliant connector 110b), a plurality of pairs of lower electrically-conductive posts 112 (e.g., each pair consisting of a first lower electrically-conductive post 112a and a second lower electrically-conductive post 112b), and a plurality of electrical lead wires 114.

Referring to FIGS. 1 to 3, the lower module frame 106 includes a first lower module sub-frame 101 and a second lower module sub-frame 103. The first lower module sub-frame 101 is adapted to be detachably coupled to, for example, a mount point of the component testing system. The second lower module sub-frame 103 is coupled to the first lower module sub-frame 101.

Within the plurality of pairs of compliant connectors 110, each compliant connector can be provided as a spring-loaded pin, or the like. Each pin may be provided as an electrically-conductive material such as copper, beryllium, gold, or the like or any combination thereof. Generally, each spring-loaded pin is biased so as to press against an electrically-conductive post of the upper module 104 (e.g., when the first lower module sub-frame 101 is coupled to a component testing system). A connector housing 105 is coupled to the second lower module sub-frame 103 and houses the plurality of pairs of compliant connectors 110.

As best shown in FIG. 3, the plurality of test contact modules 108 are secured between the first lower module sub-frame 101 and the second lower module sub-frame 103. Generally, each of the plurality of test contact modules 108 includes one or more roller test contacts (e.g., as shown at 107), one or more slider test contacts (e.g., as shown at 109), or the like or any combination thereof. As is known in the art, the carrier plate conveys a device to be tested such that it is brought into contact with the test contacts of a test module 108 and, thereafter, one or more measurements of the DUT (e.g., a measurement of the dissipation factor of the DUT) can be made. After a measurement has been made on the DUT, the carrier plate is operated to replace the as-measured device with a new device to be tested, and the measurement process can be repeated.

Referring to FIG. 3, a first end of each lead wire 114 is electrically connected to a corresponding test contact module 108, and a second end of lead wire 114 is electrically connected to an electrically-conductive post in each pair of lower electrically-conductive posts 112. Electrically-conductive posts within each pair of lower electrically-conductive posts 112 are electrically connected to each other (e.g., by a shunt 115).

Referring to FIG. 1, the upper module 104 includes a circuit housing 111 and an upper module frame 113. The upper module frame 113 is adapted to be detachably coupled to, for example, a mount point of the component testing system. The circuit housing 111 is coupled to the upper module frame 113.

Referring to FIGS. 2 to 4, the upper module 104 also includes a circuit board 116 supporting circuitry (identified generally at 118), and a plurality of pairs of upper electrically-conductive posts 120 (e.g., each pair consisting of a first upper electrically-conductive post 120a and a second upper electrically-conductive post 120b). Generally, the circuit board 116 and circuitry 118 are within the circuit housing 111, and the circuit board 116 is fixed within the upper module frame 113. Each upper electrically-conductive post within the plurality of pairs of electrically-conductive posts 120 is soldered to leads (not shown) of the circuit board 116 which, in turn, are electrically connected to the circuitry 118. Each upper electrically-conductive post may be provided as an electrically-conductive material such as copper, beryllium, gold, or the like or any combination thereof.

The circuitry 118 is operative to perform “high sense” and “high potential” measurements on a DUT that is electrically contacted to test contacts of a test module 108. Accordingly, and as best shown in FIG. 4, within each pair of lower electrically-conductive posts 112, the first lower electrically-conductive post 112a may be provided as a “high potential” post and the second lower electrically-conductive post 112b may be provided as a “high sense” post. Likewise, within each pair of compliant connectors 110, the first compliant connector 110a may be provided as a “high potential” connector and the second compliant connector 110b may be provided as a “high sense” connector. Lastly, within each pair of upper electrically-conductive posts 120, the first upper electrically-conductive post 120a may be provided as a “high potential” post and the second upper electrically-conductive post 120b may be provided as a “high sense” post.

When the lower module 102 and the upper module 104 are coupled to the component testing system, a first lower electrically-conductive post 112a, a first compliant connector post 112a and a first upper electrically-conductive post 120a may be electrically connected to each other so as to form a first conductive path. Likewise, when the lower module 102 and the upper module 104 are coupled to the component testing system, a second lower electrically-conductive post 112b, a second compliant connector post 112b and a second upper electrically-conductive post 120b may be electrically connected to each other so as to form a second conductive path. It should be noted that the first and second lower electrically-conductive posts 112a and 112b within the first and second conductive paths are part of a common pair of lower electrically-conductive posts 112; the first and second compliant connectors 110a and 110b within the first and second conductive paths are part of a common pair of compliant connectors 110; and the first and second upper electrically-conductive posts 120a and 120b within the first and second conductive paths are part of a common pair of upper electrically-conductive posts 120. As used herein, the aforementioned first and second conductive paths can, collectively, be referred to as a pair of conductive paths which are electrically connected together within the lower module 102 by a common shunt 115.

When performing the “high sense” and “high potential” measurements on the DUT, the circuitry 118 is electrically connected to first and second conductive paths in a common pair of conductive paths. Specifically, a first portion of the circuitry 118 operative to perform a “high potential” operation is electrically connected to the aforementioned first conductive path, and a second portion of the circuitry 118 operative to perform a “high sense” operation is electrically connected to the aforementioned second conductive path. However, because the first and second conductive paths are electrically connected to each other within the lower module 102 (i.e., by a shunt 115), the circuitry 118 does not perform the “high potential” and “high sense” operations on the same conductive path. Instead, the “high potential” and “high sense” operations are performed on separate conductive paths (and, thus, separate compliant conductors 110).

When performing the “high sense” and “high potential” measurements on the DUT, the circuitry 118 is operative to null out bulk resistance using an LCR or auto balancing meter, since the DF error is nearly constant. After the nulling (compensation) operation, additional measurement error from separate “force”/“sense” compliant connectors 110 is small. The resistance variation from these points has been observed to be less than 1 milliOhm at a 1 kHz operating frequency. Depending on the application, this can improve system yield by 5% or more, yet without making it any more difficult to remove the hardware for easy servicing of consumable parts.

For consumables servicing, the point of separation of the consumables-holding hardware (i.e., the lower module 102) coincides with the compliant connector 110. In this way, as the lower module 102 is removed and replaced, electrical connections can be simultaneously made or broken with no additional tools or operations. This is particularly advantageous in a high speed measurement tool where the lower module 102 can typically include 112 pairs of compliant connectors 110, and their service interval may only be 1-2 days.

The foregoing is illustrative of embodiments and examples of the invention, and is not to be construed as limiting thereof. Although a few specific embodiments and examples have been described with reference to the drawings, those skilled in the art will readily appreciate that many modifications to the disclosed embodiments and examples, as well as other embodiments, are possible without materially departing from the novel teachings and advantages of the invention. Accordingly, all such modifications are intended to be included within the scope of the invention as defined in the claims. For example, skilled persons will appreciate that the subject matter of any sentence, paragraph, example or embodiment can be combined with subject matter of some or all of the other sentences, paragraphs, examples or embodiments, except where such combinations are mutually exclusive. The scope of the present invention should, therefore, be determined by the following claims, with equivalents of the claims to be included therein.

What is claimed is:

1. An electrical measurement contacting system for use with a component testing system operable to convey devices, the electrical measurement contacting system comprising:
a first module including a test contact module having a test contact adapted to electrically contact devices conveyed by the component testing system; and
a second module including circuitry electrically coupled to the test contact module and operative to perform an electrical measurement on devices conveyed to the test contact,
wherein the circuitry is connected, within the second module, to a first conductive path and a second conductive path,
wherein the first conductive path and the second conductive path extend into the first module, and
wherein the first conductive path and the second conductive path are electrically connected to each other and to the test contact module in the first module.

2. The electrical measurement contacting system of claim 1, wherein the first module and the second module are separable from one another, and wherein each of the first conductive path and the second conductive path includes a compliant electrical connector.

3. The electrical measurement contacting system of claim 2, wherein the compliant electrical connector includes a spring-loaded pin.

4. The electrical measurement contacting system of claim 2, wherein the second module is configured to be coupled to the component testing system.

5. The electrical measurement contacting system of claim 4, wherein the first module is removable from the second module.
